(19) United States
(12) Patent Application Publication
(10) Pub. No.: US 2025/0169031 A1
(43) Pub. Date: May 22, 2025

(54) HEAT EXCHANGER FOR HIGH PERFORMANCE HEAT CHIP SETS

(71) Applicant: Mikros Technologies LLC, Claremont, NH (US)

(72) Inventors: Drew M. Matter, Hanover, NH (US); Jesse D. McGowan, Alexandria, NH (US); Joseph T. Sullivan, Hanover, NH (US); Javier A. Valenzuela, Naples, FL (US)

(21) Appl. No.: 19/033,819

(22) Filed: Jan. 22, 2025

Related U.S. Application Data
(63) Continuation of application No. 18/420,324, filed on Jan. 23, 2024, now abandoned.
(60) Provisional application No. 63/440,682, filed on Jan. 23, 2023.

(51) Int. Cl. H05K 7/20

(52) U.S. Cl. CPC H05K 7/20254; H05K 7/20272; H05K 7/20772

(57) ABSTRACT

Presently disclosed is a cold plate heat exchanger with reduced thermal resistance for use with high-performance computing chips sets used in high power density servers. The improved reduced thermal resistance cold plate includes a thin, microchannel cold plate that is pressed against a heat generating device using an elastomeric element to elastically flex the cold plate so that it conforms to the surface of the heat generating device, thereby minimizing the thermal resistance of the interface between the two.

### CROSS-REFERENCE TO RELATED APPLICATIONS

This application is a continuation of U.S. patent application Ser. No. 18/420,324, filed Jan. 23, 2024, which claims priority to and the benefit of U.S. Provisional Patent Application No. 63/440,682, filed Jan. 23, 2023, the entire disclosures of which are incorporated by reference herein.

### TECHNICAL FIELD

This disclosure relates generally to a cold plate heat exchanger with reduced thermal resistance for use with high-performance computing chips sets used in data centers to reduce energy consumption.

### BACKGROUND

The use of heat exchangers for cooling of computer hardware is known in the art. As technology in the semiconductor industry continues to advance, so too does the need for improved cooling solutions. For example, state-of-the art graphics processing units such as the H100 GPU by NVIDIA features 80 billion transistors and two types of cores that are designed to be up to 9× faster than its predecessors.

Semiconductor devices in data centers or supercomputers generate a significant amount of heat during operation and require cooling. The transistors and active components on the semiconductor of the central processing unit (CPU) or graphical processing unit (GPU) of a computer or server consume a significant amount of electricity, which is dissipated as heat, and requires active cooling to keep the silicon maximum temperature below the rated maximum temperature. For example, silicon semiconductor devices generally have maximum operating temperature limits between 80° C. and 95° C. Above these critical temperatures, semiconductor devices become more likely to malfunction, so effective cooling is needed to ensure the proper operation of a data center or supercomputer to avoid this from occurring.

The U.S. Department of Energy (DOE) recognizing the need to overcome technology barriers associated with the development of high-performance energy efficient cooling solutions for data centers has announced up to $42 million in funding to find a resolution to the problem. According to the DOE, data centers that are used to house computers, storage systems and computing infrastructure, account for approximately 2% of total U.S. electricity production while data center cooling can account for up to 40% of data center energy usage overall. Reducing the amount of energy data centers use for cooling will help to lower the operational carbon footprint associated with powering and cooling data centers and help companies and countries reach worldwide sustainability goals.

The most common form of cooling today in data centers utilizes air as the coolant. Cold air is forced into a cooling device, known as a heat sink, by a fan and heats up as it removes the heat. This hot air is then cooled by a heat rejection device that removes the heat from the air and rejects it to the ambient air outside the data center. These heat rejection devices can be, for example, a radiator, a water-cooling tower, or a compressor/chiller. The heat sink which attaches to the CPU/GPU is made of a conductive material, generally aluminum or copper, and has fins that stretch away from the CPU/GPU surface. These fins increase the surface area for which the device can transfer heat into the air and improve the heat rejection performance. These heat sinks are attached to the silicon using a thermal interface material (e.g., a thermally conductive grease or thermally-conductive compliant pad), that creates a low-resistance thermal bond between the silicon and the heat sink. These thermal interface materials are needed as the surface of both the silicon and heat sink are not perfectly flat, and air gaps between the two devices would lead to large thermal resistances, and poor cooling performance.

Prior art microchannel cold plates are rigid and do not significantly deform under the loads that can be safely applied to electronic components (20-40 psi). Some prior art cold plates are brazed to a metal manifold that distributes the coolant, thus making it rigid because of the manifold's thickness. Other prior art cold plates utilize parallel flow channels and the matrix thickness needs to be large (several mm) to reduce the pressure drop. The fins are fabricated on a metal base that is several mm thick. The tall fins and thick base result in a rigid cold plate.

Supercomputers or data centers which require more high frequency and complex calculations, often referred to as “high performance computing,” cannot be effectively cooled by air, as the heat loads in the CPU/GPUs are much higher than in a traditional data center. For these applications, liquid coolants are used to remove the heat directly from the CPU/GPU. Conventionally, a water block or cold plate is mounted directly to the CPU/GPU into which cold water is pumped and hot water exits. The hot water is then cooled back down by a heat rejection device which dissipates that heat to the outside ambient air.

In such devices, the cold plate consists of either fins or channels that are internal to the cold plate and are optimized to efficiently remove heat from the CPU/GPU. The cold plate is mounted and pushed on to the CPU/GPU with a thermal interface material (or “TIM”) in between to improve the performance and fill in potential air gaps between the cold plate and the CPU/GPU. Generally, the cost of the cold plates is higher than heat sinks used with air cooling, so liquid cooling is reserved for the CPU/GPUs, which are the highest heat output devices on a server, and thus have the highest cooling requirements. Air cooling is often used in parallel to cool the low power devices on the board, which commonly adds significant complexity to a cooling system for a data center, as parallel cooling systems for liquid and air are needed.

To address this complexity of running air and liquid cooling loops in parallel, many data centers are now using immersion liquid cooling for their high-performance computing needs. In these systems, the entire board is submerged in a dielectric fluid that is recirculated in a bath, and its sensible heat is rejected to the outside ambient air by one of the heat rejection devices mentioned above. The dielectric coolant is by nature non-conductive, so the CPU/GPUs and electronic devices are not shorted or impacted in their function in any way. Any number of known dielectric coolants may be utilized. The advantage of this approach is that low power devices (such as memory) are readily cooled and expensive heat sinks can be eliminated as the thermal properties of liquid dielectric coolant are significantly better than air. For cooling the CPU/GPU, which has a higher heat load per area, a heat sink or cold plate can be effectively used to increase the surface area for heat transfer; this heat sink may also be attached via a thermal interface material.

The above options are currently deployed in HPC data centers with varied success on the current generation of CPU/GPUs. However, two factors make the above cooling technologies insufficient for tomorrow's needs. First, CPU/GPUs will generate significantly more heat, increasing the demands on the cooling system's performance. Second, data centers are required to be more energy efficient and new guidelines require the cooling system to move more heat while using less electrical power to do so. These two compounding factors mean that cooling systems of the future will need to reduce the thermal resistance or improve their cooling performance to meet this need.

### SUMMARY

Described is a flexible cold plate assembly. In implementations, the flexible cold plate assembly includes a rigid housing configured to supply and outlet fluid from the flexible cold plate assembly, a rigid header in fluid communication with the rigid housing, a manifold in fluid communication with the rigid header, a flexible heat transfer matrix in fluid communication with the manifold, and a cover plate attached to the flexible heat transfer matrix. The manifold is compliantly connected to the cover plate and the flexible heat transfer matrix. The cover plate is hermetically sealed to the rigid housing. The flexible heat transfer matrix is configured to deform to a curvature of a heat generating device when the flexible cold plate assembly is attached to the heat generating device.

### BRIEF DESCRIPTION OF THE DRAWINGS

The disclosure is best understood from the following detailed description when read in conjunction with the accompanying drawings. It is emphasized that, according to common practice, the various features of the drawings are not to scale. On the contrary, the dimensions of the various features are arbitrarily expanded or reduced for clarity.

FIG. 1 is a side view of a flexible cold plate assembly in accordance with the present teachings.

FIG. 1A is a side view of the flexible cold plate assembly in operation with a heat generating device having a convex surface in accordance with the present teachings.

FIG. 1B is a side view of the flexible cold plate assembly ii operation with a heat generating device having a concave surface in accordance with the present teachings.

FIG. 2 is a side view of the flexible cold plate assembly in operation with load generation by compression of elastomeric manifold in accordance with the present teachings.

FIG. 2A is a side view of the flexible cold plate assembly in operation with load generation by control of coolant pressure in accordance with the present teachings.

FIG. 3 is a fluid flow diagram with a closed face normal flow microchannel matrix in accordance with the present teachings.

FIG. 3A is a fluid flow diagram with an open face normal flow microchannel matrix in accordance with the present teachings.

FIG. 4 is a perspective view of the flexible cold plate assembly in accordance with the present teachings.

FIG. 5 is an exploded view of the flexible cold plate assembly of FIG. 4 in accordance with the present teachings.

FIG. 6 is a side perspective view of the flexible cold plate assembly with an open face microchannel matrix in accordance with the present teachings.

FIG. 6A is an exploded view of a topology of a heat generating device in accordance with the present teachings.

FIG. 7 is an exploded view of the flexible cold plate assembly of FIG. 6 in accordance with the present teachings.

FIG. 8 is a side view of the flexible microchannel matrix in operation adapted for discontinuity on heat generation surface curvature in accordance with the present teachings.

FIG. 9 is an exploded view of a flexible cold plate assembly in accordance with the present teachings.

### DETAILED DESCRIPTION

The present disclosure will hereinafter be described with respect to one or more exemplary embodiments, with the understanding that the present disclosure is to be considered an exemplification and is not intended to limit the invention to the specific embodiments illustrated. It will be understood to one of skill in the art that the apparatus, system and/or method is capable of implementation in other embodiments and of being practiced or carried out in various ways. Also, the phraseology and terminology used herein is for the purpose of description and should not be regarded as limiting. Any references to examples, embodiments, components, elements or acts herein referred to in the singular may also embrace embodiments including a plurality, and any references in plural to any embodiment, component, element, or act herein may also embrace embodiments including only a singularity (or unitary structure). References in the singular or plural form are not intended to limit the presently disclosed apparatus, system and/or method, their components, acts, or elements. The use herein of “including,” “comprising,” “having,” “containing,” “involving,” and variations thereof is meant to encompass the items listed thereafter and equivalents thereof as well as additional items. References to “or” may be construed as inclusive so that any terms described using “or” may indicate any of a single, more than one, and all of the described terms. The use of the term “and” may be construed to include additional items or used as to describe alternative items.

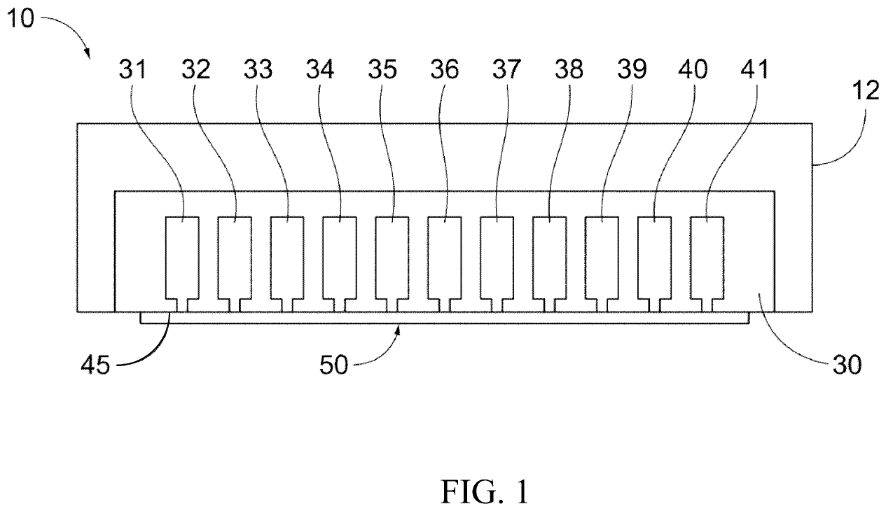

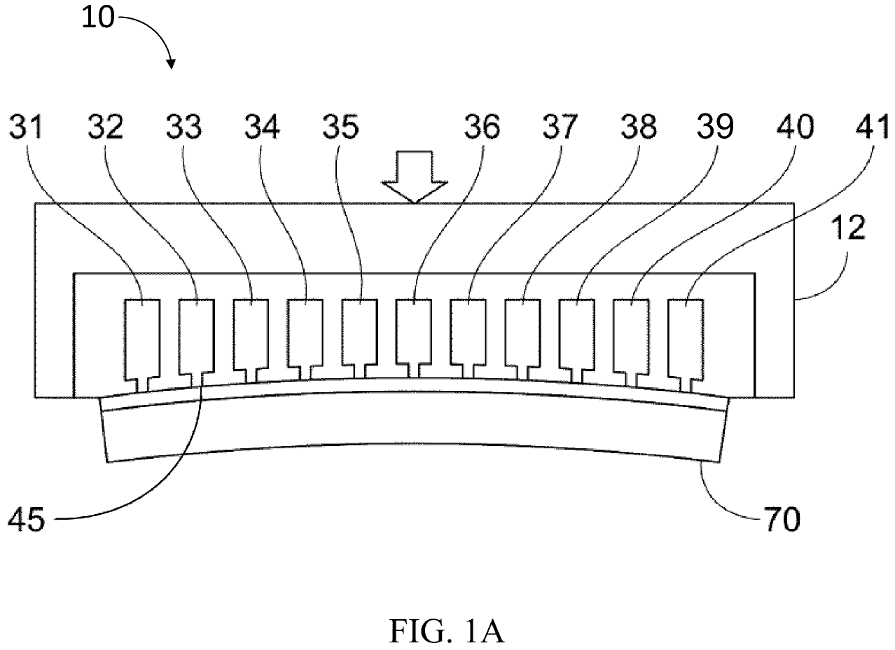

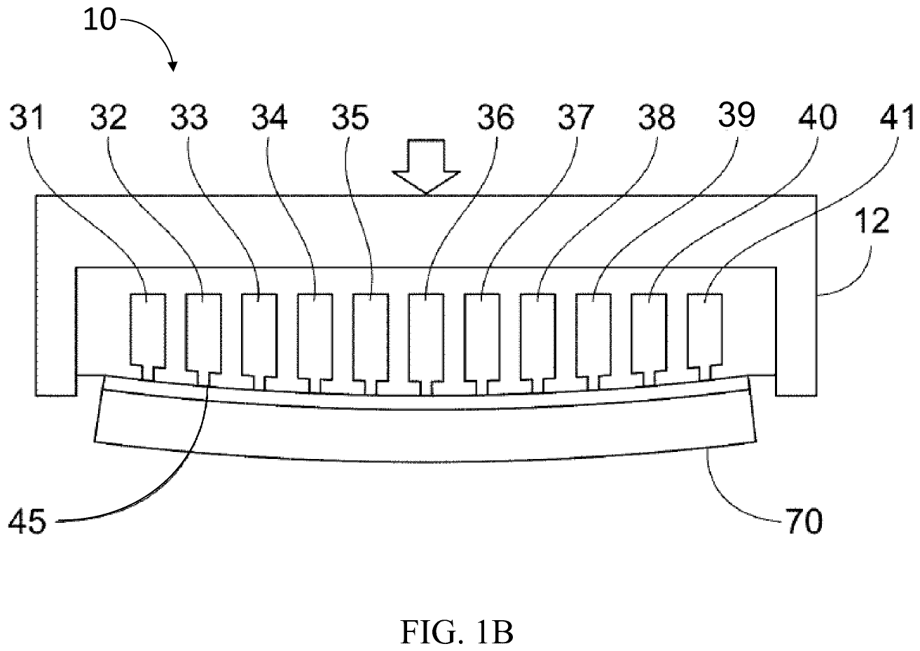

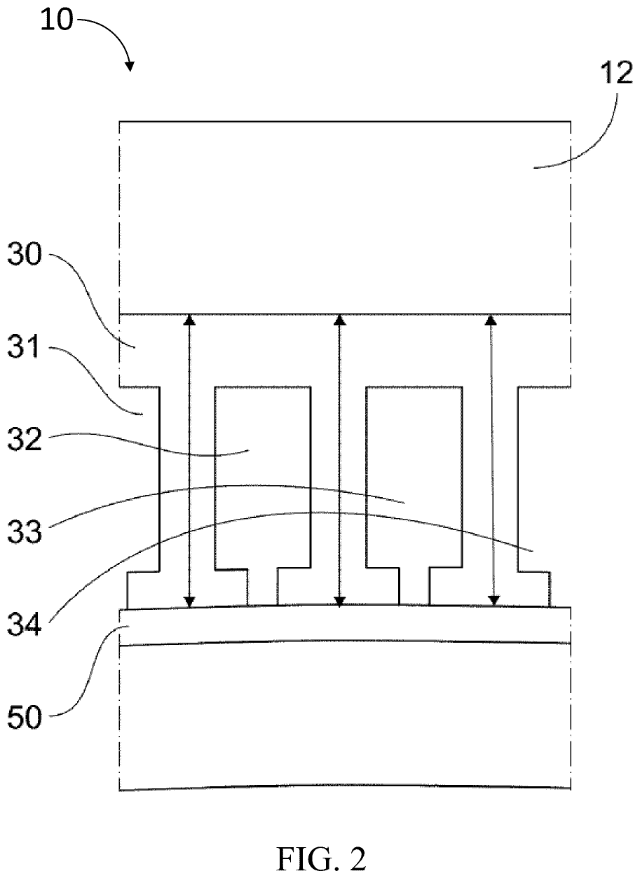

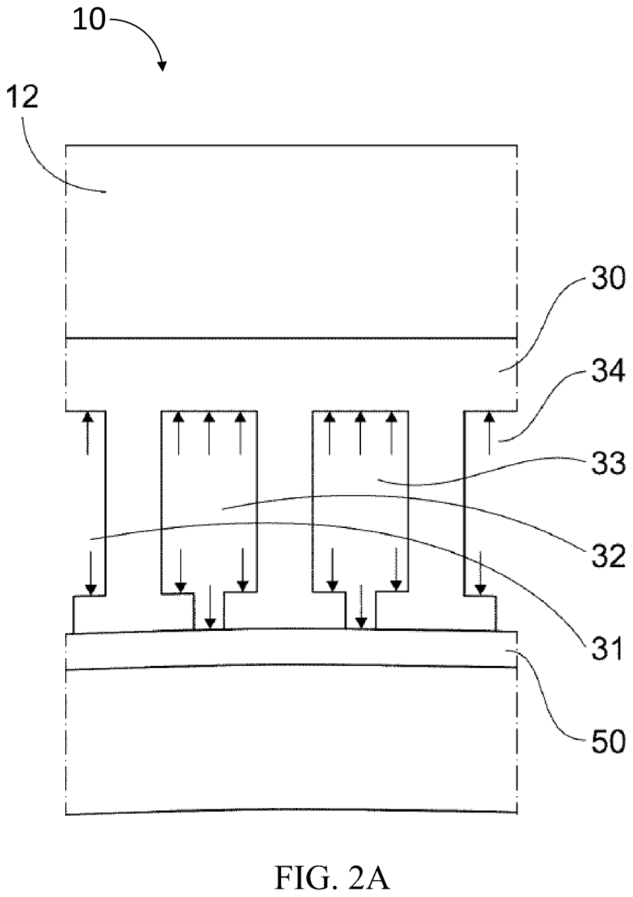

Referring initially to exemplary FIGS. 1 and 2, a thin heat transfer matrix may be fabricated using the microchannel geometries and fabrication methods described in, for example, U.S. Pat. No. 8,474,516, issued Jul. 2, 2013, titled “Heat Exchanger Having Winding Micro-channels,” assigned and/or owned by the current applicant, which is incorporated herein by reference as if set forth (the “'516 Patent”). In summary, the heat exchanger of the '516 Patent includes a heat transfer member having winding microchannels, a manifold, and a cover plate. In use, heat is transferred to, and/or from the heat exchanger over an active heat transfer area, which corresponds to the portion of the cover plate corresponding to the portion of the heat exchanger that includes the winding microchannels. The microchannels' winding design is defined by a nonlinear flow axis that has a plurality of short pitch and small amplitude undulations, which cause the flow to change directions, as well as two or more large amplitude bends that cause the flow to reverse direction. In low flow per unit area applications, the winding microchannels allow a user to customize the pressure drop to promote good flow distribution, to achieve improved heat transfer uniformity, and to enable the pressure drop to remain above the bubble point of the heat transfer structure to prevent gas blockage. The winding microchannels also increase the heat transfer coefficient. The heat transfer member includes one or more heat transfer layers, each having a plurality of inlet openings and corresponding outlet openings. Each of the winding microchannels is in fluid communication with at least one of the inlet openings and at least one of the corresponding outlet openings, such that the cooling fluid enters the inlet openings, flows along the microchannels, and exits via the outlet openings. The openings are arranged in rows through each layer, each opening extending from the first surface through to the second surface of each heat transfer layer. The manifold supplies fluid to each of the inlet openings of the heat transfer member and receives fluid from each of the outlet openings of the heat transfer member. The manifold distributes and collects the fluid throughout the active heat transfer area in order to promote uniform heat transfer throughout the area. The fluid enters the heat exchanger through an inlet port that is fluidly connected to an inlet header that distributes the fluid along the y-axis of the manifold. The fluid is then fed to inlet channels that are fluidly connected to the inlet header, such that the fluid is distributed by the inlet channels along the x-axis of the manifold. A plurality of outlet channels which are interdigitated with the inlet channels collect the exit fluid along the x axis of the manifold and carry it to the outlet header which collects the fluid along the y-axis if the manifold and carries it to the outlet port. The functions of distributing and collecting the fluid to the heat transfer surface and transferring the heat between the fluid and the surface are achieved by the manifold and the heat transfer member, respectively. This separation in functions allows the selection of the flow passage geometry in each component to the benefit of their respective functions. The configuration of the winding microchannels can be modified according to a particular application, but in all applications, the microchannel axis remains non-linear.

Using these geometries, the matrix thickness is between approximately 5 to 7 times the microchannel size to achieve a desired thermal performance. Matrices with microchannels sizes of 150 microns or less can have a thickness of approximately 1 mm or less. Moreover, the heat transfer matrices have high void fraction, with microchannels occupying between approximately 30 to 50% of the total volume of the cold plate material. The high void fraction reduces the effective modulus of elasticity of matrix. The thin geometry and lower modulus make the matrix flexible.

FIG. 1 is a side view of a flexible cold plate assembly 10 in accordance with the present teachings, FIG. 1A is a side view of the flexible cold plate assembly 10 in operation with a heat generating device 70 having a convex surface in accordance with the present teachings, and FIG. 1B is a side view of the flexible cold plate assembly 10 in operation with a heat generating device 70 having a concave surface in accordance with the present teachings. FIG. 2 is a side view of the flexible cold plate assembly 10 in operation with load generation by compression of elastomeric manifold in accordance with the present teachings. FIG. 2A is a side view of the flexible cold plate assembly 10 in operation with load generation by control of coolant pressure in accordance with the present teachings.

The flexible cold plate assembly 10 can include, but is not limited to, a rigid housing 12, a compliant manifold 30, and a flexible heat transfer matrix 50. The compliant manifold 30 can include, but is not limited to, a plurality of channels 31, 32, 33, 34, 35, 36, 37, 38, 39, 40, and 41 to supply and collect fluid from the flexible heat transfer matrix 50. The compliant manifold 30 can be fabricated out of a suitable elastomeric material (e.g. silicone) that can bend and/or deform elastically as shown for example in FIGS. 1A and 1B. The flexible heat transfer matrix 50 is attached to the compliant manifold 30. The rigid housing 12 encloses a back and sides of the compliant manifold 30 as shown in the figures herein.

Referring now also to FIGS. 1A and 1B, during operation, the flexible cold plate assembly 10 is pressed against a surface of the heat generating surface 70 using a suitable mounting force. The mounting force is distributed by the compliant manifold 30 to a back face and/or surface 45 of the flexible heat transfer matrix 50 and the flexible heat transfer matrix 50 deforms to match a curvature of the surface of the heat generating device 70. Because of varying thermal stresses, the shape of the surface of the heat generating device 70 can vary from concave (as shown in FIG. 1B) to convex (as shown in FIG. 1A) during operation. The distributed force on the back face 45 of the flexible heat transfer matrix 50 causes the curvature of the flexible heat transfer matrix 50 to follow the changes in curvature of the surface of the heat generating device 70. The load applied to the back side 45 of the flexible heat transfer matrix 50 to achieve the required deformation results from a combination of the elastic compression of the manifold material (as shown in FIG. 2) and the cooling fluid pressure (as shown in FIG. 2A). Depending on the application, it may be advantageous to rely on one or the other method to control the magnitude of the load.

The embodiments described herein include a flexible cold plate assembly with a closed face normal flow microchannel matrix and an open face normal flow microchannel matrix.

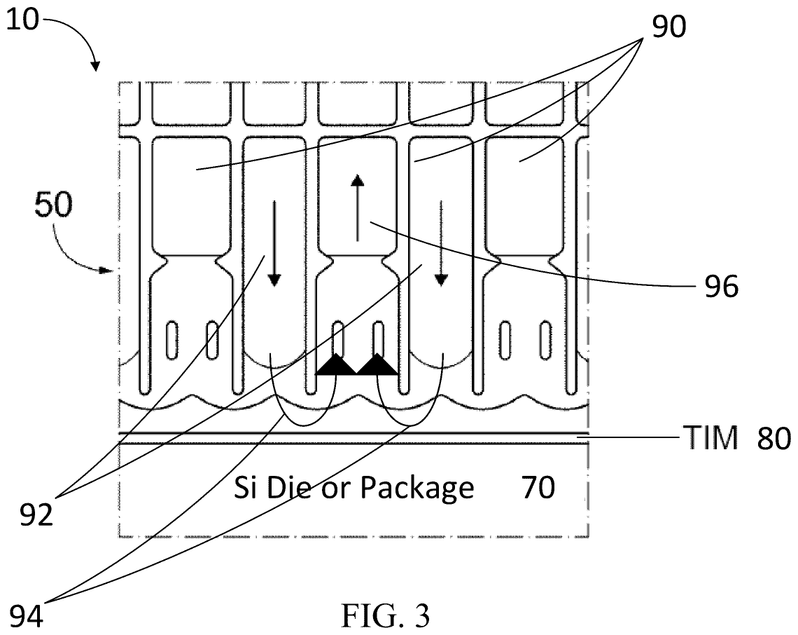

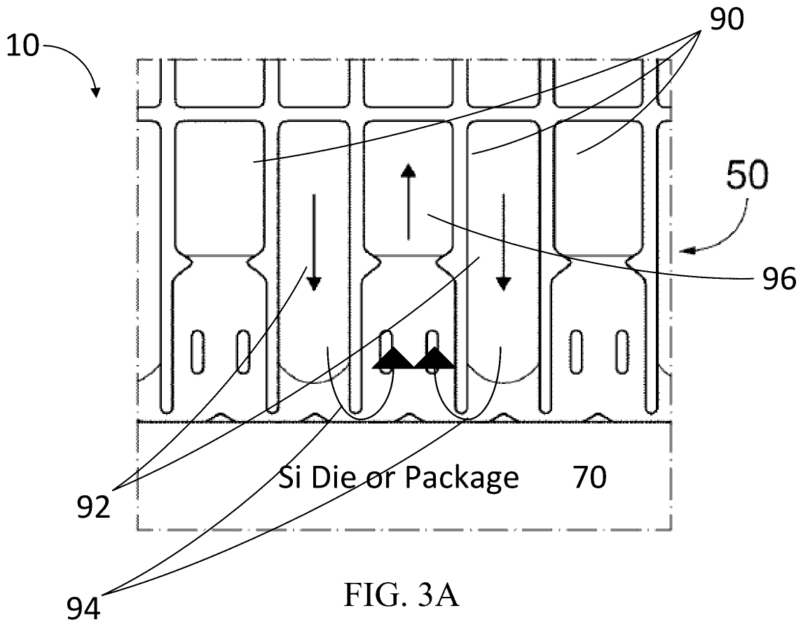

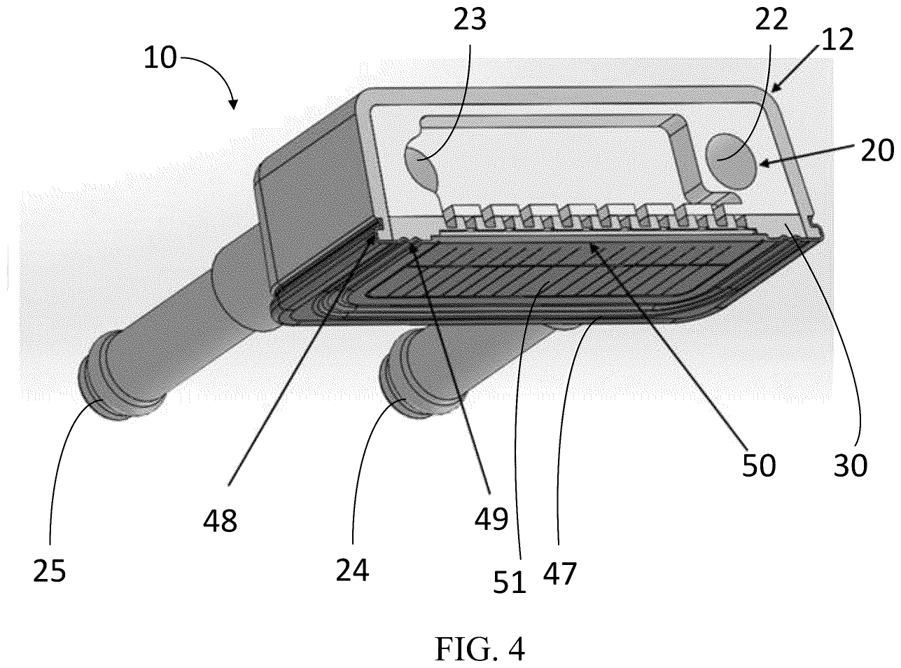

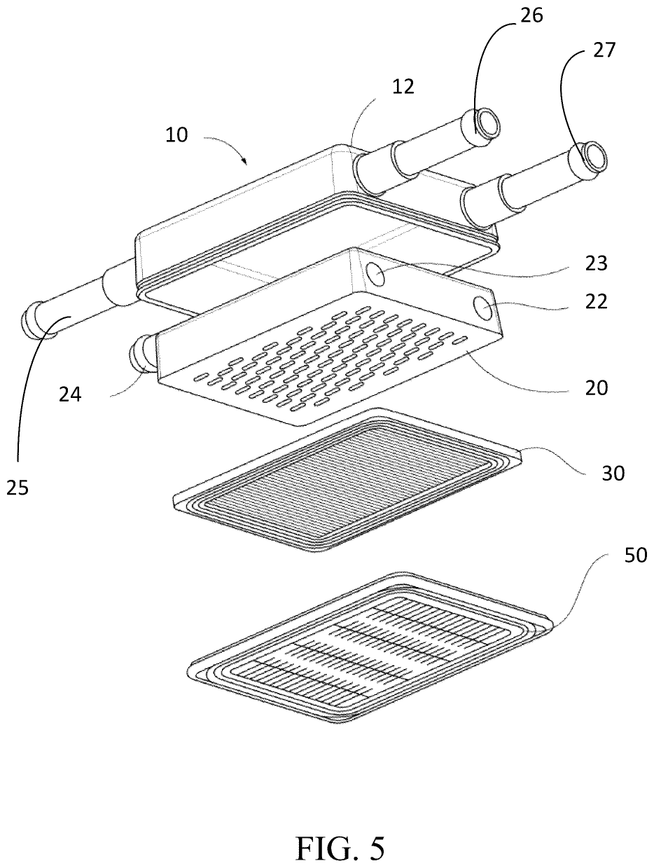

FIG. 3 is a fluid flow diagram where the flexible cold plate assembly 10 includes a flexible heat transfer matrix 50 with a closed face. The flexible heat transfer matrix 50 includes microchannels 90. The flexible heat transfer matrix 50 is thermally connected to a heat generating device 70 via a thermal interface material (“TIM”) 80. Coolant from a compliant manifold, for example, flows through the microchannels 90 toward the TIM 80 and the heat generating device 70 (flows 92), heats up (flow 94), and returns through the microchannels 90 toward the compliant manifold (flow 96). In these embodiments, the coolant in the microchannels 90 does not come in contact the heat generating device 70. This is applicable for the embodiments shown, for example, in FIGS. 4 and 5.

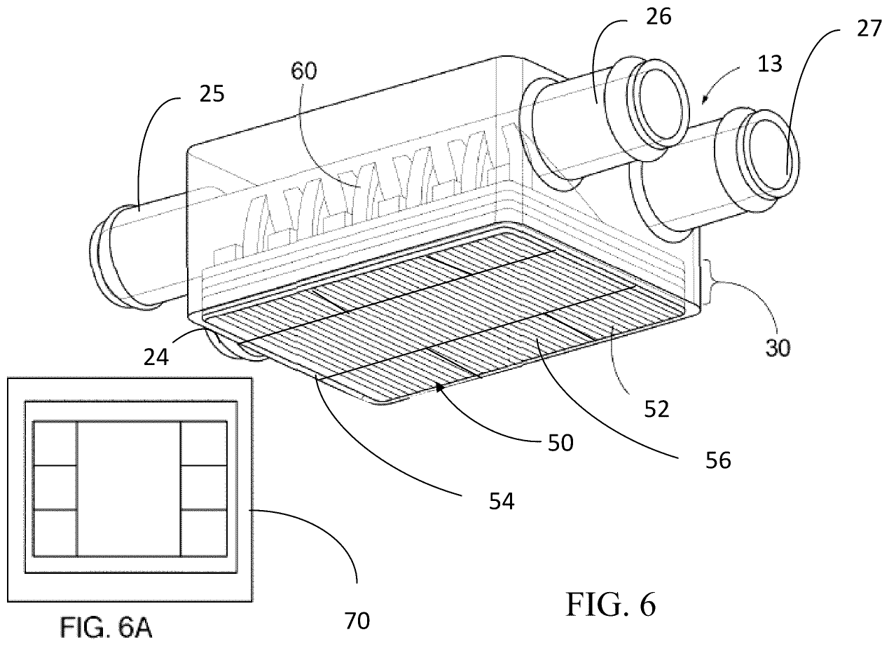

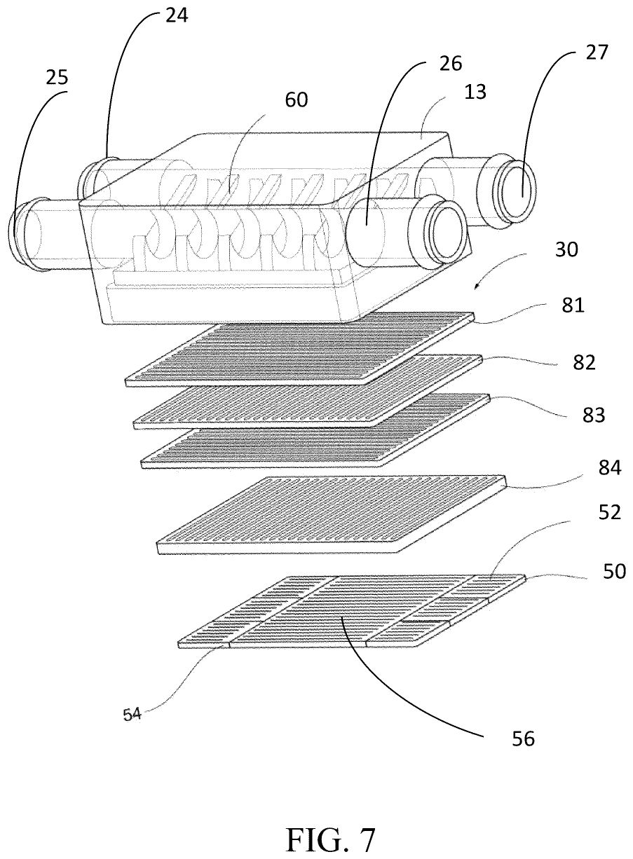

FIG. 3A is a fluid flow diagram where the flexible cold plate assembly 10 includes a flexible heat transfer matrix 50 with an open face. The flexible heat transfer matrix 50 includes microchannels 90. Coolant from a compliant manifold, for example, flows through the microchannels 90 toward the heat generating device 70 (flows 92), contacts the heat generating device 70 and heats up (flow 94), and returns through the microchannels 90 toward the compliant manifold (flow 96). In these embodiments, the microchannels 90 are open to the heat generating device 70 such that the coolant in the microchannels 90 comes in contact with the heat generating device 70. This is applicable for the embodiments shown, for example, in FIGS. 6, 6A, and 7.

FIG. 4 is a perspective view of the flexible cold plate assembly 10 in accordance with the present teachings and FIG. 5 is an exploded view of the flexible cold plate assembly 10 of FIG. 4 in accordance with the present teachings. The flexible cold plate assembly 10 can include, but is not limited to, the rigid housing 12, a rigid header 20, the compliant manifold 30, and a flexible heat transfer matrix 50 and a thin copper foil 47 which covers the flexible heat transfer matrix 50 and which is also referred to as a cover plate 47. The compliant manifold 30 bridges the gap between the flexible heat transfer matrix 50 and the rigid header 20. The rigid housing 12 can include, but is not limited to, ports 24, 25, 26, and 27. One of the pair of ports 24 and 25 or the pair of ports 26 and 27 are inlet ports and the other are outlet ports. The number of ports is illustrative and non-limiting. Various port configurations can be used without limiting the scope of the claims and specification. The rigid header 20 can include, but is not limited to, ports 22 and 23.

The flexible heat transfer matrix 50 is bonded and/or attached to the cover plate 47. The cover plate 47 is sealed at or to edges 48 of the rigid housing 12. That is, a leak-tight seal is formed between the cover plate 47 and the rigid housing 12, for example, by hermetical sealing (e.g., via crimping, bonding). The cover plate 47 forms a compliant connection or seal with the compliant manifold 30. The cover plate 47 may include corrugations 49 in a space between the flexible heat transfer matrix 50 and/or the cover plate 47 and the compliant manifold 30 to provide compliance between the compliant manifold 30 and the flexible heat transfer matrix 50 and/or the cover plate 47. The cover plate 47 may include grooves 51 on a surface facing a heat generating device to facilitate squeezing out or removing the TIM when the flexible cold plate assembly 10 is attached to a heat generating device. The grooves may be a network of grooves and/or a hierarchical network of grooves (e.g., a root groove with branch grooves).

The flexible cold plate assembly 10 of FIG. 4 and FIG. 5 is intended for application employing aqueous coolants (ethylene glycol (EG) or propylene glycol (PG) water mixtures) that require leak tight cold plates. Preferably, a low viscosity, high thermal conductivity would be used as the TIM. In one exemplary embodiment, the load required to make the flexible heat transfer matrix 50 conform to the die or heat generating device would be generated by controlling the coolant pressure inside the compliant manifold 30 as shown in FIG. 2A. The flexible heat transfer matrix 50 could be formed in a convex manner to make contact in the central portion of the silicon (e.g., the die or heat generating device) first, pushing the TIM to the outer perimeter to inhibit air pocket voids that can increase thermal resistance.

In implementations, the flexible cold plate assembly 10 of FIG. 4 and FIG. 5 can use two coolants. A dielectric coolant cools the low-power components via a recirculated immersion loop. A propylene glycol mixture cools the high power GPUs in a server using the flexible cold plate assembly 10. For example, the propylene glycol mixture could be comprised of 25% propylene glycol and 75% water. The flexible cold plate assembly 10 is designed and manufactured to lower the thermal resistance of previous microchannel cold plates. The methods are adapted to improve microchannel performance and enable higher surface area for convection to the propylene glycol mixture and reduce the core resistance by approximately 20%.

As described, the internal structure of the flexible cold plate assembly 10 is adapted to allow for the active surface to conform to the die shape. This allows minimization of the TIM bond line thickness between the flexible cold plate assembly 10 and chip case, which can be a thermal resistance bottleneck in current systems. In one embodiment, the TIM bond line thickness is reduced from approximately 100 microns to 25 microns.

FIG. 6 is a side perspective view of the flexible cold plate assembly 10 with an open face microchannel matrix in accordance with the present teachings, FIG. 6A is an exploded view of a topology of a heat generating device 70 in accordance with the present teachings, and FIG. 7 is an exploded view of the flexible cold plate assembly 10 of FIG. 6 in accordance with the present teachings. The flexible cold plate assembly 10 can include, but is not limited to, an integrated or combined housing and header structure 13 (“housing structure”), a manifold 30, and the flexible heat transfer matrix 50. The housing structure 13 may include barbs 60 for flow topology. The housing structure 13 may include ports 24, 25, 26, and 27. The manifold 30 may include manifold layers 81, 82, 83, and 84.

The embodiment of FIGS. 6, 6A, and 7 is intended for use in immersion cooling systems. In such systems, all the electronic components are immersed in a circulating dielectric bath. In the immersed cooling application, the flexible cold plate assembly 10 does not need to be leak tight, and that allows greater freedom in the implementation of the flexible cold plate assembly 10. In this embodiment, the overall thermal resistance between the incoming coolant, and the active regions of the silicon (e.g., heat generating device 70) is reduced. This is primarily done by eliminating the use of the traditional thermal interface materials that generally mate the flexible cold plate assembly 10 to the silicon. Instead, the lower-most microchannels are open, and the liquid dielectric coolant comes in direct contact with the silicon, as described in further detail below.

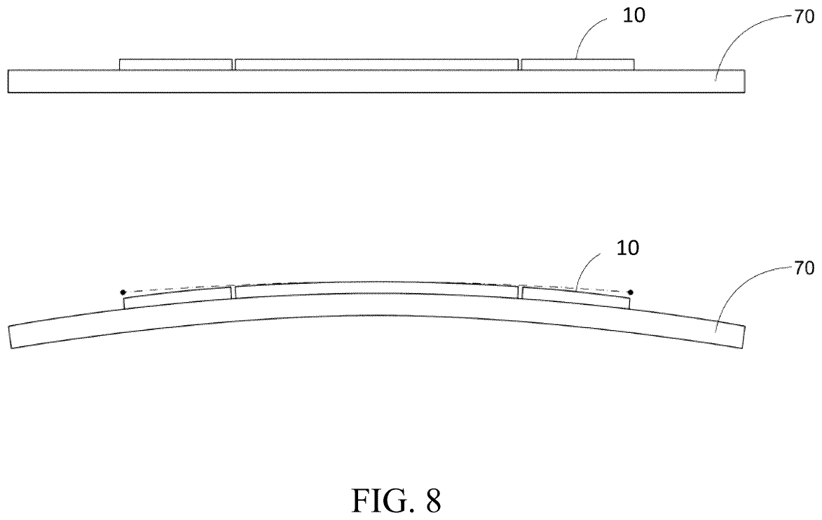

As described herein above, and as shown in FIG. 6A, the heat generating device 70 can include low power or low heat generating sections and high power or high generating sections. The flexible heat transfer matrix 50 can be segmented into flexible heat transfer matrix segments 52 and 54 so that the size of the plurality of each heat transfer matrix segment 52 and 54 is the same as that of the heat generating device 70 it is cooling. This segmentation may also be referred to as “tiles.” This segmentation, if utilized, allows accommodation of the discontinuities in the curvature of the die surface observed in multichip devices as illustrated in FIG. 8, which is a side view of the flexible heat transfer matrix 50 in operation adapted for discontinuity on a heat generation surface curvature in accordance with the present teachings. As shown, the flexible heat transfer matrix 50, as a result of being thin and having multiple segments, has flexibility to better conform to the heat generation surface curvature of the heat generating device 70. Because the silicon wafer (e.g., the heat generating device 70) may bow or curve during operation, portions of the flexible cold plate assembly 10 such as the flexible heat transfer matrix 50 and the manifold 30 (when made of compliant materials as described herein), are flexible to conform to the surface topology of the silicon (e.g., the heat generating device 70). As the copper portion of the flexible cold plate assembly 10, i.e., the flexible heat transfer matrix 50, is both thin (<1 mm) and/or segmented into tiles 52 and 54, this allows the flexible heat transfer matrix 50 to bend and conform to the die shape.

The plurality of heat transfer matrix segments or tiles 52 and 54 that contain fluidic channels and/or microchannels 56 can each be tailored to the heat flux or power dissipation for different regions of the silicon chip. In many silicon dies, the heat output varies as a function of position. This is especially true for multi-chip modules, where memory units are placed next to the die. These locations have lower cooling requirements. Using heat transfer matrix segments or tiles 52 and 54 with embedded fluidic channels and/or microchannels 56 enables each one to be tailored for pressure drop and performance. In some cases, a group of heat transfer matrix segments or tiles 52 and 54 that are similarly tailored can be positioned together in the same zone. For example, in one non-limiting embodiment, tiles placed in a first zone above the memory chips would have a higher pressure drop than the ones placed in a second zone above the CPU/GPU where most of the heat is generated, and all the tiles would receive coolant in parallel. This would ensure that the majority of the flow will go into the CPU/GPU, and a reduced amount of coolant is provided to the memory chips which have reduced cooling requirements. This ensures that the coolant flow rate is kept at a minimum.

Additionally, the tiled approach will allow the copper channels (i.e., the microchannels 56 in the flexible heat transfer matrix 50) to conform overstep changes in height on multi-chip modules. For example, the memory chips and the CPU/GPU are often on different pieces of silicon, and there is thus a discontinuity in the surface profile between these pieces of silicon. If the tiles are separated along this boundary between the silicon chips, they can each conform to their respective silicon chips without kinks in their profile, thus ensuring intimate contact over the entire silicon's' surfaces.

As stated with reference to FIGS. 6, 6A, and FIG. 7, the microchannels 56 are exposed at the bottom of the flexible heat transfer matrix 50 and are not covered. For example, as shown in FIGS. 3, 4, and 5, the bottom of the flexible heat transfer matrix 50 would be covered by TIM when applied to a device in the field. Because the microchannels 56 are exposed and not covered, this embodiment may also be referred to as the open microchannel matrix or flexible heat transfer matrix 50. The open flexible heat transfer matrix 50 allows direct contact and heat transfer between the coolant and the surface of the heat generating device 70. The coolant also serves as a thermal interface material filling the microscopic voids at the interface. During fabrication, the surface of the heat generating device 70 as well as that of the open flexible heat transfer matrix 50 are smoothed. For example, the surfaces may be lapped and polished so that there is close contact between them when they are pressed together during operation.

During use, a distributed pressure is applied across the open flexible heat transfer matrix 50 to allow it to bend and conform to the die shape. To do this, a layered structure of different materials may be utilized in the cold plate construction. As shown in FIG. 7 and with reference to FIG. 8, the bottom layer or open flexible heat transfer matrix 50 may be made of copper, and contains fluidic channels and/or microchannels 56. This is where the heat transfer is performed. The layer(s) above the open flexible heat transfer matrix 50 and internal to the housing structure 12 are called manifold layers (e.g., the manifold 30 including the manifold layers 81-84) and are responsible for directing fluid into and out of the copper channels and/or microchannels 56. The manifold 30 will be both flexible and compliant. The manifold 30 can be comprised of a plurality of layers, such as the manifold layers 81-84. In one embodiment, the manifold layer 30 may be made of either silicone or a compliant plastic and is stacked between the open flexible heat transfer matrix 50 and a third layer, the housing structure 12. The third or top layer is made of a rigid layer which is held firmly in place by the mounting hardware outboard of the CPU/GPU package. In one embodiment, this third rigid layer also contains fluidic ports for the inlet and outlet to the flexible cold plate assembly 10, such as the ports 24-27. This layering enables the copper surface, i.e., of the open flexible heat transfer matrix 50, to conform and bend to the silicon surface's shape, even as it changes during heat-up and cool-down cycles.

The virtue of being in an immersion system means that the coolant can come in direct contact with the silicon without disturbing its operation or function. Additionally, leaks in the cold plate are not a concern, as the entire system is submerged in coolant. Also, the outlet from the cold plate can simply discharge in one or many directions into the immersion bath. One of ordinary skill in the art would readily understand that the outlet(s) of the cold plate can be directly at other high-power devices that have stringent cooling requirements.

In a variation on the embodiment, the matrices could retain their bottom face (closed matrix) and a low viscosity, high thermal conductivity material could be used at the thermal interface.

As described for the FIG. 6 implementation, the propylene glycol coolant loop is eliminated, and the dielectric coolant is used in the flexible cold plate assembly 10 and as an immersion coolant. The improved microchannel designs are constructed and arranged to allow for very low pressure drops to enable the high flow rates required to reduce fluid thermal resistance. The new normal flow microchannel designs are adapted for use with dielectrics that will enable core resistances to meet ARPA-E target, for example. In certain embodiments, traditional TIM is eliminated, and a dielectric coolant is utilized with an extremely smooth and well-mated surface to reduce the overall interface resistance.

The elimination of the largest thermal resistance in the network i.e., the traditional TIM that is used to mate the flexible cold plate assembly 10 to the silicon, achieves the target cooling objectives. In lieu of a traditional thermal interface material, the improved cold plate system utilizes microchannels that are an open construction to allow direct contact between liquid dielectric coolant and the silicon. However, impingement of coolant onto the silicon alone may not provide sufficient cooling for certain applications. Additionally, the new open channel design aids in thermally syncing the cold plate's copper channel walls to the silicon, acting as a liquid thermal interface. The copper channel walls add significant surface area for convective heat transfer from to the coolant, and greatly enhance the performance of the cold plate.

Providing an excellent thermal interface between the copper surface and the silicon is needed when using the open matrix design of FIGS. 6 and 7. To achieve the goal of an ultra-low thermal resistance, the copper walls and the silicon are brought into intimate, close contact. Due to the low thermal conductivity of most dielectric coolants, the distances here may be below a fraction of a micron. Fortunately, silicon is very smooth, with most roughness measured in nanometers. To reduce the roughness of the copper suitable for smooth contact with the silicon, the copper may be lapped and polished to ensure that the roughness is below 200 nm, or may be otherwise smoothed as would be known to those of skill in the art.

Minimizing roughness is a first step to achieve good thermal contact between the silicon and copper. Most silicon wafers are bowed or curved, which means the copper cold plate needs to be flexible to conform to the surface topology of the silicon. As such, the copper portion of the cold plate should be both thin (<1 mm) and segmented into tiles to allow it to bend and conform to the die shape during heating and cooling.

A distributed pressure may be applied across the copper to allow it bend and conform to the die shape. To do this, a layered structure of different materials may be utilized in the cold plate construction, as discussed above. The bottom layer may be made of copper and contains fluidic channels for heat transfer. The second layer is a manifold layer that is responsible for directing fluid into and out of the copper channels. This manifold layer may be both flexible and compliant. In one embodiment, the manifold layer is made of either silicone or a compliant plastic. The third layer on top is made of a rigid layer which may be pushed down by mounting hardware outboard of the GPU package. This third rigid layer may also contain fluidic ports for the inlet and outlet to the cold plate. This stack-up design enables the copper surface to conform and bend to the silicon surface's shape, even as it changes during heat-up and cool-down cycles.

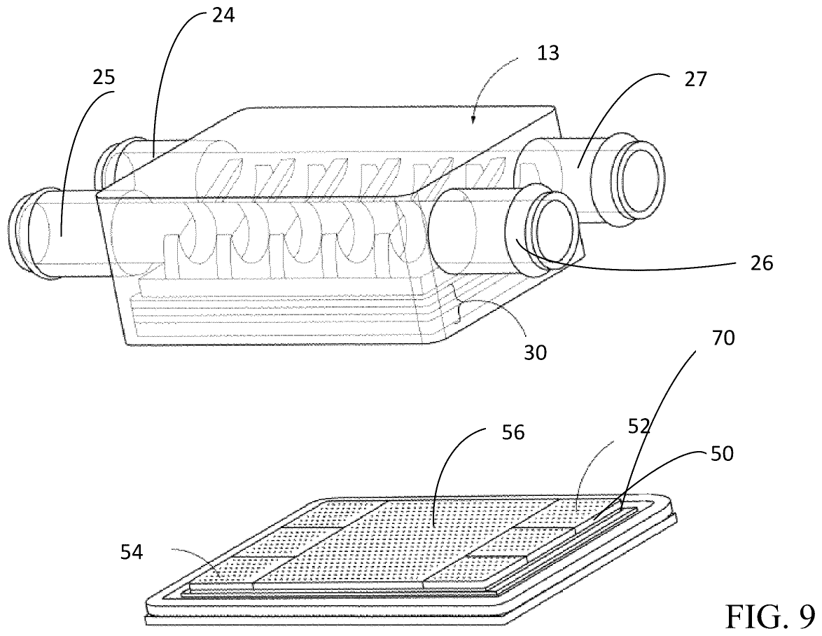

FIG. 9 is an exploded view of a flexible cold plate assembly in accordance with the present teachings. The flexible cold plate assembly 10 can include, but is not limited to, the housing structure 13, the manifold 30, and a flexible heat transfer matrix 50. The housing structure 13 may include barbs 60 for flow topology. The housing structure 13 may include ports 24, 25, 26, and 27. The manifold 30 may include the manifold layers 81, 82, 83, and 84 as shown in FIG. 7. The flexible heat transfer matrix 50 may include heat transfer matrix segments or tiles 52 and 54 and the heat transfer matrix segments or tiles 52 and 54 may include microchannels 56.

This embodiment is also intended for use with a dielectric coolant. The geometry of the components may be the same or similar as that of the previous embodiment of FIG. 6, except that the flexible heat transfer matrix 50 is in a closed configuration. That is, the microchannel matrices or microchannels 56 are closed, and they are soldered to the die or heat generating device 70. Because the matrices. e.g., the flexible heat transfer matrix 50, are very thin and have void fractions greater than approximately 35%, their yield strength is much lower than that of the silicon dies. During cooldown from soldering temperatures, the matrices will yield limiting the magnitude of the compressive stresses on the silicon die.

Other interface options between the silicon and the copper are also envisioned, including soldering the individual tiles on the silicon die directly as shown in FIG. 9, or other methods as would be known to those of skill in the art. This is expected to result in a very low resistance at the copper/silicon interface but may also include an additional metallization step to the top of the silicon die. This metallization step may be needed if testing shows that the contact resistance between the silicon and the copper is higher than expected.

Having thus described several aspects of at least one disclosed example, it is to be appreciated that various alterations, modifications, and improvements will readily occur to those skilled in the art, without departing from the spirit and scope of the invention as defined by the appended claims. Therefore, the claims are not to be limited to the specific example(s) depicted herein. For example, the features of one example disclosed above can be used with the features of another example. Furthermore, various modifications and rearrangements of the parts may be made without departing from the spirit and scope of the underlying inventive concept. Such alterations, modifications, and improvements are intended to be part of this disclosure and are intended to be within the scope of the examples discussed herein. Thus, the details of these components as set forth in the above-described examples should not limit the scope of the claims.

Further, the purpose of the Abstract is to enable the U. S. Patent and Trademark Office, and the public generally, and especially the scientists, engineers and practitioners in the art who are not familiar with patent or legal terms or phraseology, to determine quickly from a cursory inspection the nature and essence of the technical disclosure of the application. The Abstract is neither intended to define the claims of the application nor is intended to be limiting on the claims in any way.

What is claimed is:

1. A flexible cold plate assembly, comprising:
a rigid housing configured to supply and outlet fluid from the flexible cold plate assembly;
a rigid header in fluid communication with the rigid housing;
a manifold in fluid communication with the rigid header;
a flexible heat transfer matrix in fluid communication with the manifold, the flexible heat transfer matrix configured to deform to a curvature of a heat generating device when the flexible cold plate assembly is attached to the heat generating device; and
a cover plate attached to the flexible heat transfer matrix,
wherein the manifold is compliantly connected to the cover plate and the flexible heat transfer matrix, and
wherein the cover plate is hermetically sealed to the rigid housing.

2. The flexible cold plate assembly of claim 1, wherein the manifold is constructed of an elastomeric material.

3. The flexible cold plate assembly of claim 1, wherein the manifold includes a plurality of coolant distribution channels to supply and return fluid from the flexible heat transfer matrix.

4. The flexible cold plate assembly of claim 3, wherein the flexible heat transfer matrix includes a plurality of microchannels that are in fluid communication with the plurality of coolant distribution channels.

5. The flexible cold plate assembly of claim 1, wherein the flexible heat transfer matrix is configured to flex between a convex and a concave position, thereby allowing the flexible heat transfer matrix to adapt to changes in the curvature of the heat generating device and remain attached.

6. The flexible cold plate assembly of claim 1, wherein the cover plate includes a plurality of corrugations in a space between the cover plate and the manifold to provide compliance between the manifold, the flexible heat transfer matrix, and the cover plate.

7. The flexible cold plate assembly of claim 1, wherein the cover plate includes a plurality grooves on a surface of the cover plate facing the heat generating device to facilitate removal of thermal interface material when the flexible cold plate assembly is attached to the heat generating device.

8. The flexible cold plate assembly of claim 1, wherein load generation on the flexible heat transfer matrix is generated from elastic compression of the manifold when the flexible cold plate assembly is attached to the heat generating device.

9. The flexible cold plate assembly of claim 1, wherein the rigid housing encloses portions of the rigid header, the manifold, and the flexible heat transfer matrix.

10. The flexible cold plate assembly of claim 1, wherein the fluid is an aqueous coolant.

11. The flexible cold plate assembly of claim 1, wherein the flexible heat transfer matrix is made of a high thermal conductivity metal.

12. A flexible cold plate assembly, comprising:
a manifold in fluid communication with a housing structure;
a flexible heat transfer matrix in fluid communication with the manifold, the flexible heat transfer matrix configured to conform with a surface of a heat generating device when the flexible cold plate assembly is attached to the heat generating device; and
a cover plate attached to the flexible heat transfer matrix and hermetically sealed to the housing structure,
wherein the manifold is compliantly connected to the cover plate and the flexible heat transfer matrix.

13. The flexible cold plate assembly of claim 12, wherein the manifold is constructed of an elastomeric material.

14. The flexible cold plate assembly of claim 12, wherein:
the manifold includes a plurality of fluid distribution channels to supply and return fluid from the flexible heat transfer matrix to the housing structure; and
the flexible heat transfer matrix includes a plurality of microchannels that are in fluid communication with the plurality of fluid distribution channels.

15. The flexible cold plate assembly of claim 12, wherein the flexible heat transfer matrix is configured to flex between a convex and a concave position to adapt to changes in the surface of the heat generating device.

16. The flexible cold plate assembly of claim 12, wherein the cover plate includes a plurality of corrugations in a space between the cover plate and the manifold to provide conformity between the manifold, the flexible heat transfer matrix, and the cover plate.

17. The flexible cold plate assembly of claim 12, wherein the cover plate includes a plurality of grooves on a surface of the cover plate facing the heat generating device to facilitate removal of thermal interface material when the flexible cold plate assembly is attached to the heat generating device.

18. The flexible cold plate assembly of claim 12, wherein load generation on the flexible heat transfer matrix is generated from elastic compression of the manifold when the flexible cold plate assembly is attached to the heat generating device.

19. The flexible cold plate assembly of claim 1, wherein the fluid is an aqueous coolant.

20. The flexible cold plate assembly of claim 1, wherein the flexible heat transfer matrix is made of a high thermal conductivity metal.
